(19) United States
(12) Patent Application Publication
(10) Pub. No.: US 2020/0266125 A1
(43) Pub. Date: Aug. 20, 2020

(54) SEMICONDUCTOR DEVICE

(71) Applicant: SK hynix Inc., Gyeonggi-do (KR)

(72) Inventors: Min-Su PARK, Seoul (KR); Geun-Ho CHOI, Gyeonggi-do (KR)

(21) Appl. No.: 16/710,012

(22) Filed: Dec. 11, 2019

(30) Foreign Application Priority Data
Feb. 15, 2019 (KR) 10-2019-0017844

(51) Int. Cl. H01L 23/473; H01L 23/31; H01L 23/48; H01L 23/482

(52) U.S. Cl. CPC H01L 23/473; H01L 23/4825; H01L 23/481; H01L 23/3114

(57) ABSTRACT

A semiconductor package includes a semiconductor chip including at least one vertical hole that penetrates therethrough in a vertical direction, and a mold covering the semiconductor chip, and including at least one first horizontal hole and at least one second horizontal hole that are formed in a horizontal direction, wherein the first horizontal hole and the second horizontal hole are connected through the vertical hole.

### CROSS-REFERENCE TO RELATED APPLICATION

This application claims priority under 35 U.S.C. § 119 to Korean Patent Application No. 10-2019-0017844, filed on Feb. 15, 2019 the disclosure of which is incorporated herein by reference in its entirety.

### BACKGROUND

### 1. Field

Various embodiments of the present invention relate to a semiconductor design technique, and more particularly, to a semiconductor device.

### 2. Description of the Related Art

A cryogenic system provides a cryogenic environment for a stable operation of a semiconductor package. However, even though the semiconductor package is placed in the cryogenic environment, the semiconductor package generates heat during operation. Due to the generated heat, the semiconductor package may have poor operating characteristics. For example, in a case where the semiconductor package includes a DRAM, due to the generated heat, the retention time of data stored in memory cells of the DRAM is reduced, and a data sensing margin deteriorates.

Moreover, the higher the speed and capacity of the semiconductor package are, the more heat management is required.

### SUMMARY

Various embodiments of the present invention are directed to a semiconductor package having a structure capable of cooling not only the surface but also the inside thereof, in a cryogenic environment.

In accordance with an embodiment, a semiconductor package includes: a semiconductor chip including at least one vertical hole that penetrates therethrough in a vertical direction; and a mold covering the semiconductor chip, and including at least one first horizontal hole and at least one second horizontal hole that are formed in a horizontal direction, wherein the first horizontal hole and the second horizontal hole are connected through the vertical hole.

One end of the first horizontal hole may be opened to an external, and the other end of the first horizontal hole may be blocked from the external, and one of the second horizontal hole may be opened to the external, and the other end of the second horizontal hole may be blocked from the external.

The one end of the first horizontal hole and the one end of the second horizontal hole may be formed in the same direction.

The one end of the first horizontal hole and the one end of the second horizontal hole may be formed in different directions.

The first horizontal hole may be formed at higher location of the mold than the second horizontal hole, and wherein a refrigerant for the refrigerant inducement path may be introduced through any one of the first horizontal hole and the second horizontal hole, and the refrigerant may flow out through the other one of the first horizontal hole and the second horizontal hole.

The refrigerant may include liquid nitrogen.

In accordance with an embodiment, a semiconductor package includes: a semiconductor chip including a plurality of vertical holes that penetrate therethrough in a vertical direction and at least one horizontal hole that is formed in a horizontal direction and connected to at least two vertical holes of the plurality of vertical holes; and a mold covering the semiconductor chip, and including at least one first horizontal hole and at least one second horizontal hole that are formed in a horizontal direction, wherein the first horizontal hole and the second horizontal hole are connected through the at least one horizontal hole and the at least two vertical holes.

The horizontal hole may be formed in an interlayer dielectric layer included in the semiconductor chip.

One end of the first horizontal hole may be opened to an external, and the other end of the first horizontal hole may be blocked from the external, and one end of the second horizontal hole may be opened to the external, and the other end of the second horizontal hole may be blocked from the external.

The one end of the first horizontal hole and the one end of the second horizontal hole may be formed in different directions from each other.

A refrigerant for the refrigerant inducement path may be introduced through any one of the first horizontal hole and the second horizontal hole, and the refrigerant may flow out through the other one of the first horizontal hole and the second horizontal hole.

The refrigerant may include liquid nitrogen.

The first horizontal hole may be formed at higher location of the mold than the second horizontal hole.

In accordance with an embodiment, a semiconductor package includes: a semiconductor chip; a mold covering the semiconductor chip; and at least one refrigerant inducement path penetrating the mold and the semiconductor chip.

The at least one refrigerant inducement path may have any one of a mash pattern, a stepped pattern and an uneven pattern.

The refrigerant inducement path may include a first opening formed on one side of the mold and a second opening formed on any one of the one side and the other side of the mold.

A refrigerant for the refrigerant inducement path may be introduced through any one of the first and second openings, and the refrigerant may flow out through the other one of the first and second openings, and the first opening may be formed at higher location of the mold than the second opening.

The refrigerant may include liquid nitrogen.

The semiconductor chip may include a plurality of vertical holes that penetrate therethrough in a vertical direction.

The semiconductor chip may further include at least one horizontal hole that is formed in a horizontal direction and connected to at least two vertical holes of the plurality of vertical holes.

### BRIEF DESCRIPTION OF THE DRAWINGS

FIG. 1 is a block diagram illustrating a cooling system in accordance with an embodiment of the present invention.

FIG. 2 is a perspective view illustrating an example of a semiconductor package shown in FIG. 1.

FIG. 3 is a cross-sectional view illustrating the semiconductor package shown in FIG. 2.

FIG. 4 is a perspective view illustrating another example of a semiconductor package shown in FIG. 1.

FIG. 5 is a cross-sectional view illustrating the semiconductor package shown in FIG. 4.

FIG. 6 is a perspective view illustrating yet another example of a semiconductor package shown in FIG. 1.

FIG. 7 is a cross-sectional view illustrating the semiconductor package shown in FIG. 6.

FIG. 8 is a perspective view illustrating still another example of a semiconductor package shown in FIG. 1.

FIG. 9 is a cross-sectional view illustrating the semiconductor package shown in FIG. 8.

### DETAILED DESCRIPTION

Various embodiments of the present invention are described below in more detail with reference to the accompanying drawings. These embodiments are provided so that this disclosure is thorough and complete, and fully conveys the scope of the present invention to those skilled in the art. Throughout the disclosure, like reference numerals refer to like parts throughout the various figures and embodiments of the present invention.

It is noted that reference to “an embodiment,” “another embodiment” or the like does not necessarily mean only one embodiment, and different references to any such phrase are not necessarily to the same embodiment(s).

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

As used herein, singular forms may include the plural forms as well and vice versa, unless the context clearly indicates otherwise. The articles ‘a’ and ‘an’ as used in this application and the appended claims should generally be construed to mean ‘one or more’ unless specified otherwise or it is clear from context to be directed to a singular form.

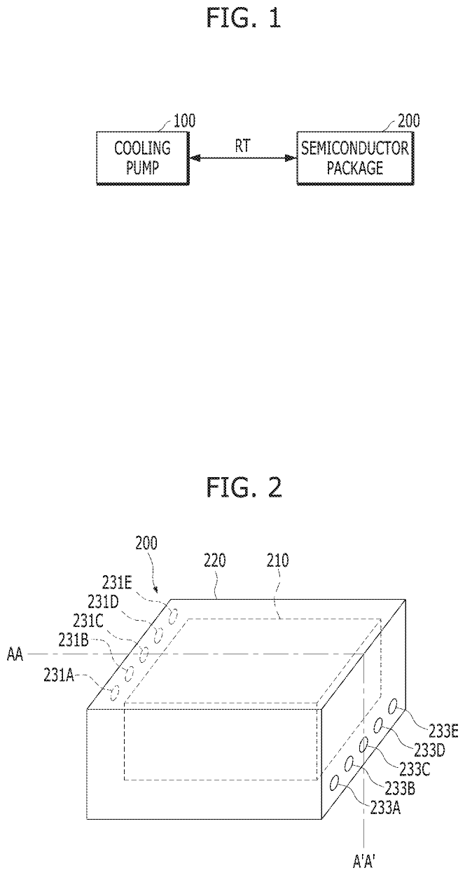

FIG. 1 is a block diagram illustrating a cooling system in accordance with an embodiment of the present invention.

Referring to FIG. 1, the cooling system may include a cooling pump 100 and a semiconductor package 200.

The cooling pump 100 may provide and receive a refrigerant RT to allow the semiconductor package 200 to operate in a cryogenic environment. For example, the cooling pump 100 may provide the refrigerant RT in a liquid state to the semiconductor package 200, receive the refrigerant RT in a gaseous state, which is vaporized through heat absorption inside the semiconductor package 200, and liquefy the refrigerant RT in the gaseous state into the refrigerant RT in the liquid state.

The refrigerant RT may include liquid nitrogen. Since the vaporization temperature of the liquid nitrogen is approximately 77K, the cryogenic environment may have a temperature of approximately 77K. Since the liquid nitrogen is less expensive than a refrigerant such as liquid helium, it is an excellent cooling material in terms of cost competitiveness.

The semiconductor package 200 will be described below with reference to FIGS. 2 to 9.

FIG. 2 is a perspective view illustrating an example of the semiconductor package 200 shown in FIG. 1.

Referring to FIG. 2, the semiconductor package 200 may include a semiconductor chip 210, a mold 220 and a plurality of refrigerant inducement paths (not illustrated).

The semiconductor chip 210 may include CMOS devices capable of operating stably in the cryogenic environment. For example, the semiconductor chip 210 may include a DRAM including the CMOS devices. Since the DRAM rarely requires a refresh operation in the cryogenic environment, the DRAM is more advantageous in terms of power consumption when operating in the cryogenic environment than when operating in a room temperature environment.

The mold 220 may be a structure for covering the semiconductor chip 210.

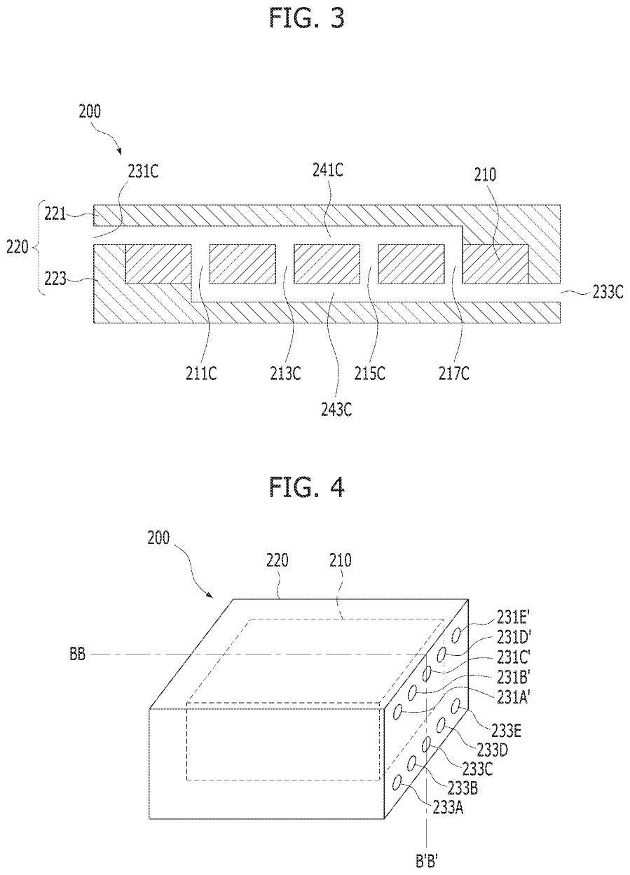

The refrigerant inducement paths may penetrate the mold 220 and the semiconductor chip 210 in a mesh pattern (refer to FIG. 3). The refrigerant inducement paths may include first openings 231A, 231B, 231C, 231D and 231E and second openings 233A, 233B, 233C, 233D and 233E, respectively. The first openings 231A, 2318, 231C, 231D and 231E may be formed on one side of the mold 220, and the second openings 233A, 233B, 233C, 233D and 233E may be formed on the other side of the mold 220. For example, a first opening 231A of a first refrigerant inducement path among the refrigerant inducement paths may be formed on the left side of the mold 220, and a second opening 233A of the first refrigerant inducement path may be formed on the right side of the mold 220.

The refrigerant RT in a liquid state may be introduced through the first openings 231A, 231B, 231C, 231D and 231E, and the refrigerant RT in a gaseous state may flow out through the second openings 233A, 233B, 233C, 233D and 233E.

FIG. 3 is a cross-sectional view illustrating the semiconductor package 200 shown in FIG. 2. For example, FIG. 3 illustrates the cross-sectional view taken along the line AA-A′A′ to representatively describe a third refrigerant inducement path among the refrigerant inducement paths.

Referring to FIG. 3, the semiconductor chip 210 may include a plurality of vertical holes 211C, 213C, 215C and 217C that vertically penetrate therethrough. The vertical holes 211C, 213C, 215C and 217C may be holes that were perforated during a process for forming silicon through vias (TSVs). In this case, the holes perforated to form the silicon through vias (TSVs) are not filled with conductors but remain empty, thereby being used as the respective vertical holes 211C, 213C, 215C and 217C.

The mold 220 may include a top mold 221 and a bottom mold 223. The top mold 221 may be formed on the top surface of the semiconductor chip 210, and the bottom mold 223 may be formed on the bottom surface of the semiconductor chip 210.

The top mold 221 may include a plurality of first horizontal holes formed in a horizontal direction therewithin. For example, a first horizontal hole 241C corresponding to the third refrigerant inducement path may be formed in a horizontal direction. One end of the first horizontal hole 241C may be opened to the outside of the semiconductor package 200, and the other end of the first horizontal hole 241C may be blocked from the outside of the semiconductor package 200. One end of the first horizontal hole 241C may be the first opening 231C. The first horizontal hole 241C may be connected to one end of each of the vertical holes 211C, 213C, 215C and 217C. The top surface of the semiconductor chip 210 may be exposed to the first horizontal hole 241C.

The bottom mold 223 may include a plurality of second horizontal holes formed in a horizontal direction therewithin. For example, a second horizontal hole 243C corresponding to the third refrigerant inducement path may be formed in a horizontal direction.

One end of the second horizontal hole 243C may be opened to the outside of the semiconductor package 200, and the other end of the second horizontal hole 243C may be blocked from the outside of the semiconductor package 200. The one end of the second horizontal hole 243C may be formed in the opposite direction of the one end of the first horizontal hole 241C. The one end of the second horizontal hole 243C may be the second opening 233C. The second horizontal hole 243C may be connected to the other end of each of the vertical holes 211C, 213C, 215C and 217C. The bottom surface of the semiconductor chip 210 may be exposed to the second horizontal hole 243C.

As described above, the first horizontal hole 241C, the vertical holes 211C, 213C, 215C and 217C and the second horizontal hole 243C are connected to one another, thereby serving as the third refrigerant inducement path of the refrigerant inducement paths.

FIG. 4 is a perspective view illustrating another example of the semiconductor package 200 shown in FIG. 1.

Referring to FIG. 4, the semiconductor package 200 may include a semiconductor chip 210, a mold 220 and a plurality of refrigerant inducement paths (not illustrated).

The semiconductor chip 210 may include CMOS devices capable of operating stably in the cryogenic environment. For example, the semiconductor chip 210 may include a DRAM including the CMOS devices.

The mold 220 may be a structure for covering the semiconductor chip 210.

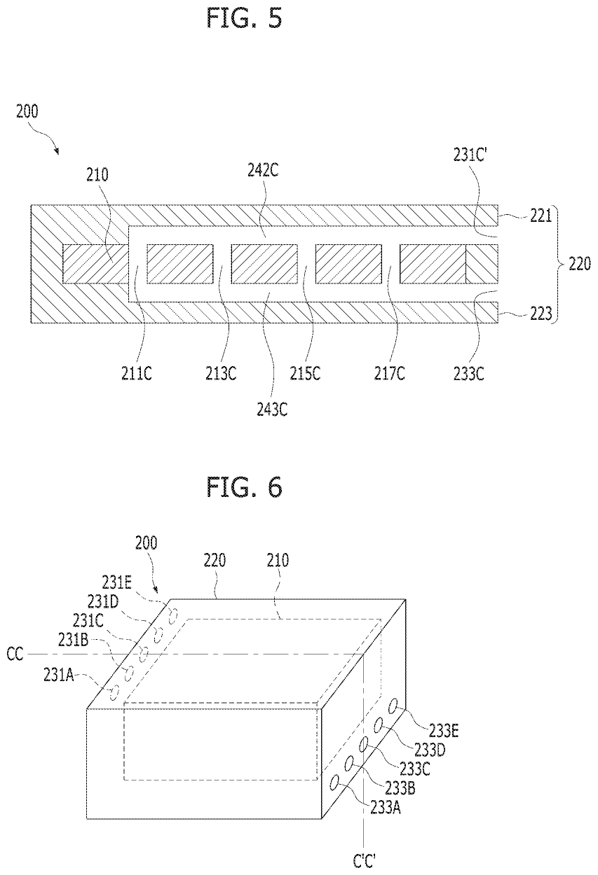

Each of the refrigerant inducement paths may penetrate the mold 220 and the semiconductor chip 210 in a mesh pattern (refer to FIG. 5). The refrigerant inducement paths may include first openings 231A′, 2313′, 231C′, 231D′ and 231E′ and second openings 233A, 233B, 233C, 233D and 233E, respectively. The first openings 231A′, 2313′, 231C′, 231D′ and 231E′ and the second openings 233A, 233B, 233C, 233D and 233E may be all formed on one side of the mold 220. For example, both of the first and second openings 231A′ and 233A of a first refrigerant inducement path among the refrigerant inducement paths may be formed on the right side of the mold 220.

The refrigerant RT in a liquid state may be introduced through the first openings 231A′, 2313′, 231C′, 231D′ and 231E′, and the refrigerant RT of a gaseous state may flow out through the second openings 233A, 233B, 233C, 233D and 233E.

FIG. 5 is a cross-sectional view illustrating the semiconductor package 200 shown in FIG. 4. For example, FIG. 5 illustrates the cross-sectional view taken along the line BB-B′B′ to representatively describe a third refrigerant inducement path among the refrigerant inducement paths.

Referring to FIG. 5, the semiconductor chip 210 may include a plurality of vertical holes 211C, 213C, 215C and 217C that vertically penetrate therethrough. The vertical holes 211C, 213C, 215C and 217C may be holes that were perforated during a process for forming silicon through vias (TSVs). In this case, the holes perforated to form the silicon through vias (TSVs) are not filled with conductors but remain empty, thereby being used as the vertical holes 211C, 213C, 215C and 217C.

The mold 220 may include a top mold 221 and a bottom mold 223. The top mold 221 may be formed on the top surface of the semiconductor chip 210, and the bottom mold 223 may be formed on the bottom surface of the semiconductor chip 210.

The top mold 221 may include a plurality of first horizontal holes formed in a horizontal direction therewithin. For example, a first horizontal hole 242C corresponding to the third refrigerant inducement path may be formed in a horizontal direction. One end of the first horizontal hole 242C may be opened to the outside of the semiconductor package 200, and the other end of the first horizontal hole 242C may be blocked from the outside of the semiconductor package 200. The one end of the first horizontal hole 242C may be the first opening 231C′. The first horizontal hole 242C may be connected to one end of each of the vertical holes 211C, 213C, 215C and 217C. The top surface of the semiconductor chip 210 may be exposed to the first horizontal hole 242C.

The bottom mold 223 may include a plurality of second horizontal holes formed in a horizontal direction therewithin. For example, a second horizontal hole 243C corresponding to the third refrigerant inducement path may be formed in a horizontal direction. One end of the second horizontal hole 243C may be opened to the outside of the semiconductor package 200, and the other end of the second horizontal hole 243C may be blocked from the outside of the semiconductor package 200. The one end of the second horizontal hole 243C may be formed in the same direction as the one end of the first horizontal hole 242C. The one end of the second horizontal hole 243C may be the second opening 233C. The second horizontal hole 243C may be connected to the other end of each of the vertical holes 211C, 213C, 215C and 217C. The bottom surface of the semiconductor chip 210 may be exposed to the second horizontal hole 243C.

As described above, the first horizontal hole 242C, the vertical holes 211C, 213C, 215C and 217C and the second horizontal hole 243C are connected to one another, thereby serving as the third refrigerant inducement path of the refrigerant inducement paths.

FIG. 6 is a perspective view illustrating yet another example of the semiconductor package 200 shown in FIG. 1.

Referring to FIG. 6, the semiconductor package 200 may include a semiconductor chip 210, a mold 220 and a plurality of refrigerant inducement paths (not illustrated).

The semiconductor chip 210 may include CMOS devices capable of operating stably in the cryogenic environment. For example, the semiconductor chip 210 may include a DRAM including the CMOS devices.

The mold 220 may be a structure for covering the semiconductor chip 210.

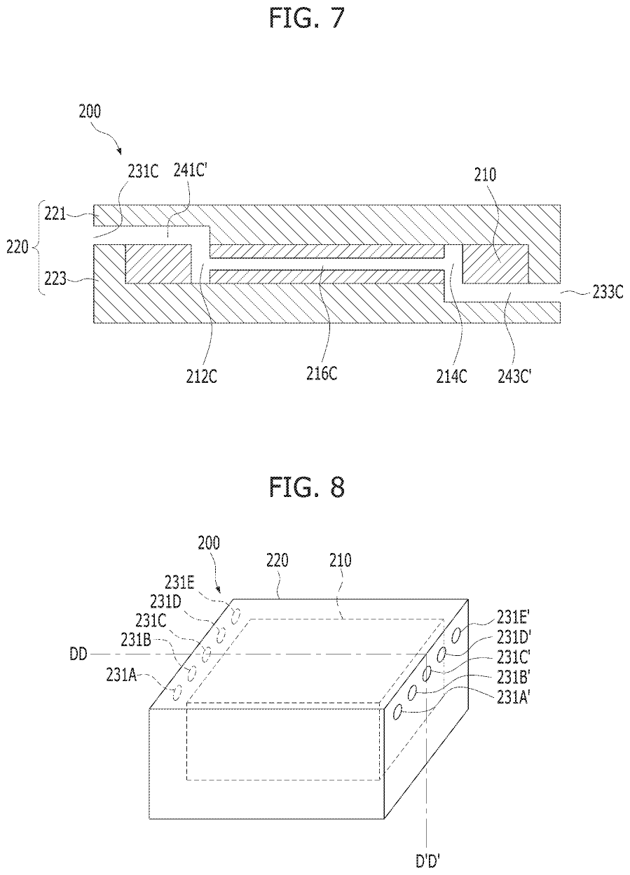

Each of the refrigerant inducement paths may penetrate the mold 220 and the semiconductor chip 210 in a stepped pattern (refer to FIG. 7). The refrigerant inducement paths may include first openings 231A, 231B, 231C, 231D and 231E and second openings 233A, 233B, 233C, 233D and 233E, respectively. The first openings 231A, 231B, 231C, 231D and 231E may be formed on one side of the mold 220, and the second openings 233A, 233B, 233C, 233D and 233E may be formed on the other side of the mold 220. For example, a first opening 231A of a first refrigerant inducement path among the refrigerant inducement paths may be formed on the left side of the mold 220, and a second opening 233A of the first refrigerant inducement path may be formed on the right side of the mold 220.

The refrigerant RT in a liquid state may be introduced through the first openings 231A, 231B, 231C, 231D and 231E, and the refrigerant RT of a gaseous state may flow out through the second openings 233A, 2333, 233C, 233D and 233E.

FIG. 7 is a cross-sectional view illustrating the semiconductor package 200 shown in FIG. 6. For example, FIG. 7 illustrates the cross-sectional view taken along the line CC-C′C′ to representatively describe a third refrigerant inducement path among the refrigerant inducement paths.

Referring to FIG. 7, the semiconductor chip 210 may include a plurality of vertical holes 212C and 214C that vertically penetrate therethrough. The vertical holes 212C and 214C may be holes that were perforated during a process for forming silicon through vias (TSVs). In this case, the holes perforated to form the silicon through vias (TSVs) are not filled with conductors but remain empty, thereby being used as the vertical holes 212C and 214C.

The semiconductor chip 210 may include a plurality of horizontal holes formed in a horizontal direction therewithin. For example, a horizontal hole 216C corresponding to the third refrigerant inducement path may be formed in a horizontal direction. The horizontal hole 216C may be connected to each of the vertical holes 212C and 214C. The horizontal hole 216C may be formed in an interlayer dielectric layer included in the semiconductor chip 210. Although not illustrated, the interlayer dielectric layer may include a layer in which a metal wiring, i.e., a metal layer, is formed on an active region of the semiconductor chip 210, the active region including a region in which the CMOS devices are formed.

The mold 220 may include a top mold 221 and a bottom mold 223. The top mold 221 may be formed on the top surface of the semiconductor chip 210, and the bottom mold 223 may be formed on the bottom surface of the semiconductor chip 210.

The top mold 221 may include a plurality of first horizontal holes formed in a horizontal direction therewithin. For example, a first horizontal hole 241C′ corresponding to the third refrigerant inducement path may be formed in a horizontal direction. One end of the first horizontal hole 241C′ may be opened to the outside of the semiconductor package 200, and the other end of the first horizontal hole 241C′ may be blocked from the outside of the semiconductor package 200. The one end of the first horizontal hole 241C′ may be the first opening 231C. The first horizontal hole 241C′ may be connected to one end of any one of the vertical holes 212C and 214C. For example, the first horizontal hole 241C′ may be connected to the vertical hole 212C of the vertical holes 212C and 214C, which is the closest to the outside in a horizontal direction on the left side of the semiconductor chip 210.

The bottom mold 223 may include a plurality of second horizontal holes formed in a horizontal direction therewithin. For example, a second horizontal hole 243C′ corresponding to the third refrigerant inducement path may be formed in a horizontal direction. One end of the second horizontal hole 243C′ may be opened to the outside of the semiconductor package 200, and the other end of the second horizontal hole 243C′ may be blocked from the outside of the semiconductor package 200. The one end of the second horizontal hole 243C′ may be formed in the opposite direction of the one end of the first horizontal hole 241C′. The one end of the second horizontal hole 243C′ may be the second opening 233C. The second horizontal hole 243C′ may be connected to the other end of the other one of the vertical holes 212C and 214C. For example, the second horizontal hole 243C′ may be connected to the vertical hole 214C of the vertical holes 212C and 214C, which is the closest to the outside in a horizontal direction on the right side of the semiconductor chip 210.

As described above, the first horizontal hole 241C′, the vertical holes 212C and 214C and the second horizontal hole 243C′ are connected to one another, thereby serving as the third refrigerant inducement path of the refrigerant inducement paths.

FIG. 8 is a perspective view illustrating still another example of the semiconductor package 200 shown in FIG. 1.

Referring to FIG. 8, the semiconductor package 200 may include a semiconductor chip 210, a mold 220 and a plurality of refrigerant inducement paths (not illustrated).

The semiconductor chip 210 may include CMOS devices capable of operating stably in the cryogenic environment. For example, the semiconductor chip 210 may include a DRAM including the CMOS devices.

The mold 220 may be a structure for covering the semiconductor chip 210.

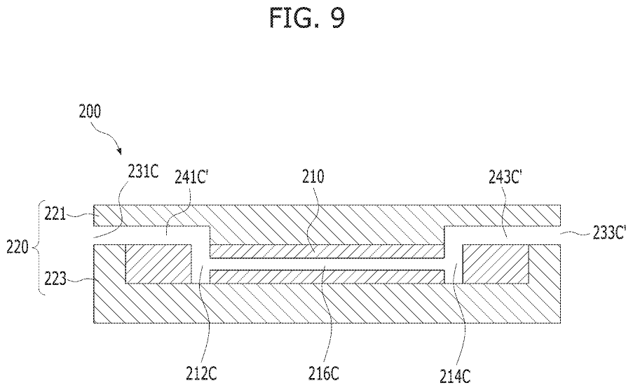

Each of the refrigerant inducement paths may penetrate the mold 220 and the semiconductor chip 210 in an uneven pattern (refer to FIG. 9). The refrigerant inducement paths may include first openings 231A, 231B, 231C, 231D and 231E and second openings 233A″, 233B′, 233C′, 233D′ and 233E′, respectively. The first openings 231A, 231B, 231C, 231D and 231E may be formed on one side of the mold 220, and the second openings 233A′, 233B′, 233C′, 233D′ and 233E′ may be formed on the other side of the mold 220. For example, a first opening 231A of a first refrigerant inducement path among the refrigerant inducement paths may be formed on the left side of the mold 220, and a second opening 233A′ of the first refrigerant inducement path may be formed on the right side of the mold 220.

The refrigerant RT in a liquid state may be introduced through the first openings 231A, 231B, 231C, 231D and 231E, and the refrigerant RT in a gaseous state may flow out through the second openings 233A′, 233B′, 233C′, 233D′ and 233E′.

FIG. 9 is a cross-sectional view illustrating the semiconductor package 200 shown in FIG. 8. For example, FIG. 9 illustrates the cross-sectional view taken along the line DD-D′D′ to representatively describe a third refrigerant inducement path of the refrigerant inducement paths.

Referring to FIG. 9, the semiconductor chip 210 may include a plurality of vertical holes 212C and 214C that vertically penetrate therethrough. The vertical holes 212C and 214C may be holes that were perforated during a process for forming silicon through vias (TSVs). In this case, the holes perforated to form the silicon through vias (TSVs) are not filled with conductors but remain empty, thereby being used as the vertical holes 212C and 214C.

The semiconductor chip 210 may include a plurality of horizontal holes formed in a horizontal direction therewithin. For example, a horizontal hole 216C corresponding to the third refrigerant inducement path may be formed in a horizontal direction. The horizontal hole 216C may be connected to each of the vertical holes 212C and 214C. The horizontal hole 216C may be formed in an interlayer dielectric layer included in the semiconductor chip 210. Although not illustrated, the interlayer dielectric layer may include a layer in which a metal wiring, i.e., a metal layer, is formed on an active region of the semiconductor chip 210, the active region including a region in which the CMOS devices are formed.

The mold 220 may include a top mold 221 and a bottom mold 223. The top mold 221 may be formed on the top surface of the semiconductor chip 210, and the bottom mold 223 may be formed on the bottom surface of the semiconductor chip 210.

The top mold 221 may include a plurality of horizontal holes formed in a horizontal direction therewithin. For example, a first horizontal hole 241C′ corresponding to the third refrigerant inducement path may be formed in a horizontal direction. One end of the first horizontal hole 241C′ may be opened to the outside of the semiconductor package 200, and the other end of the first horizontal hole 241C′ may be blocked from the outside of the semiconductor package 200. The one end of the first horizontal hole 241C′ may be the first opening 231C. The first horizontal hole 241C′ may be connected to one end of any one of the vertical holes 212C and 214C. For example, the first horizontal hole 241C′ may be connected to the vertical hole 212C of the vertical holes 212C and 214C, which is the closest to the outside in a horizontal direction on the left side of the semiconductor chip 210.

The top mold 221 may further include a plurality of horizontal holes formed in a horizontal direction therewithin. For example, a second horizontal hole 243C′ corresponding to the third refrigerant inducement path may be formed in a horizontal direction. One end of the second horizontal hole 243C′ may be opened to the outside of the semiconductor package 200, and the other end of the second horizontal hole 243C′ may be blocked from the outside of the semiconductor package 200. The one end of the second horizontal hole 243C′ may be formed in the opposite direction of the one end of the first horizontal hole 241C′. The one end of the second horizontal hole 243C′ may be the second opening 233C′. The second horizontal hole 243C′ may be connected to the other end of the other one of the vertical holes 212C and 214C. For example, the second horizontal hole 243C′ may be connected to the vertical hole 214C of the vertical holes 212C and 214C, which is the closest to the outside in a horizontal direction on the right side of the semiconductor chip 210.

As described above, the first horizontal hole 241C′, the vertical holes 212C and 214C and the second horizontal hole 243C′ are connected to one another, thereby serving as the third refrigerant inducement path of the refrigerant inducement paths.

As is apparent from the above descriptions, it is possible to form the paths through which the refrigerant may be introduced into the semiconductor package, thereby cooling not only the surface of the semiconductor package but also the inside of the semiconductor package in a cryogenic environment.

In accordance with the embodiments of the present invention, the semiconductor package has a structure in which the inside as well as the surface thereof may be cooled in a cryogenic environment, thereby being more safely protected from heat generation.

While the present invention has been illustrated and described with respect to specific embodiments, the disclosed embodiments are not intended to be restrictive. Further, it is noted that the present invention may be achieved in various ways through substitution, change, and modification, as those skilled in the art will recognize in light of the present disclosure, without departing from the spirit and/or scope of the present disclosure. The present invention is intended to embrace all such substitutions, changes and modifications that fall within the scope of the following claims.

What is claimed is:

1. A semiconductor package comprising:
a semiconductor chip including at least one vertical hole that penetrates therethrough in a vertical direction; and
a mold covering the semiconductor chip, and including at least one first horizontal hole and at least one second horizontal hole that are formed in a horizontal direction,
wherein the first horizontal hole and the second horizontal hole are connected through the vertical hole.

2. The semiconductor package of claim 1, wherein one end of the first horizontal hole is opened to an external, and the other end of the first horizontal hole is blocked from the external, and
one end of the second horizontal hole is opened to the external, and the other end of the second horizontal hole is blocked from the external.

3. The semiconductor package of claim 2, wherein the one end of the first horizontal hole and the one end of the second horizontal hole are formed in the same direction.

4. The semiconductor package of claim 2, wherein the one end of the first horizontal hole and the one end of the second horizontal hole are formed in different directions.

5. The semiconductor package of claim 1, wherein the first horizontal hole is formed at higher location of the mold than the second horizontal hole, and
wherein a refrigerant for the refrigerant inducement path is introduced through any one of the first horizontal hole and the second horizontal hole, and the refrigerant flows out through the other one of the first horizontal hole and the second horizontal hole.

6. The semiconductor package of claim 5, wherein the refrigerant includes liquid nitrogen.

7. A semiconductor package comprising:
a semiconductor chip including a plurality of vertical holes that penetrate therethrough in a vertical direction and at least one horizontal hole that is formed in a horizontal direction and connected to at least two vertical holes of the plurality of vertical holes; and
a mold covering the semiconductor chip, and including at least one first horizontal hole and at least one second horizontal hole that are formed in a horizontal direction,
wherein the first horizontal hole and the second horizontal hole are connected through the at least one horizontal hole and the at least two vertical holes.

8. The semiconductor package of claim 6, wherein the horizontal hole is formed in an interlayer dielectric layer included in the semiconductor chip.

9. The semiconductor package of claim 6, wherein one end of the first horizontal hole is opened to an external, and the other end of the first horizontal hole is blocked from the external, and
one end of the second horizontal hole is opened to the external, and the other end of the second horizontal hole is blocked from the external.

10. The semiconductor package of claim 9, wherein the one end of the first horizontal hole and the one end of the second horizontal hole are formed in different directions from each other.

11. The semiconductor package of claim 6, wherein a refrigerant for the refrigerant inducement path is introduced through any one of the first horizontal hole and the second horizontal hole, and the refrigerant flows out through the other one of the first horizontal hole and the second horizontal hole.

12. The semiconductor package of claim 11, wherein the refrigerant includes liquid nitrogen.

13. The semiconductor package of claim 11, wherein the first horizontal hole is formed at higher location of the mold than the second horizontal hole.

14. A semiconductor package comprising:
a semiconductor chip;
a mold covering the semiconductor chip; and
at least one refrigerant inducement path penetrating the mold and the semiconductor chip.

15. The semiconductor package of claim 14, wherein the at least one refrigerant inducement path has any one of a mash pattern, a stepped pattern and an uneven pattern.

16. The semiconductor package of claim 14, wherein the refrigerant inducement path includes a first opening formed on one side of the mold and a second opening formed on any one of the one side and the other side of the mold.

17. The semiconductor package of claim 15, wherein a refrigerant for the refrigerant inducement path is introduced through any one of the first and second openings, and the refrigerant flows out through the other one of the first and second openings, and
the first opening is formed at higher location of the mold than the second opening.

18. The semiconductor package of claim 17, wherein the refrigerant includes liquid nitrogen.

19. The semiconductor package of claim 14, wherein the semiconductor chip includes a plurality of vertical holes that penetrate therethrough in a vertical direction.

20. The semiconductor package of claim 19, wherein the semiconductor chip further includes at least one horizontal hole that is formed in a horizontal direction and connected to at least two vertical holes of the plurality of vertical holes.
